(19) United States
(12) Patent Application Publication
(10) Pub. No.: US 2021/0278461 A1
(43) Pub. Date: Sep. 9, 2021

(54) DIGITAL CIRCUIT MONITORING DEVICE

(71) Applicant: STMicroelectronics SA, Montrouge (FR)

(72) Inventors: Ricardo GOMEZ GOMEZ, Grenoble (FR); Sylvain CLERC, Grenoble (FR)

(73) Assignee: STMicroelectronics SA, Montrouge (FR)

(21) Appl. No.: 17/189,984

(22) Filed: Mar. 2, 2021

(30) Foreign Application Priority Data
Mar. 5, 2020 (FR) 2002212

(51) Int. Cl. G01R 31/317; G01R 31/3177; H03K 3/03

(52) U.S. Cl. CPC G01R 31/31726; H03K 3/0315; G01R 31/3177

(57) ABSTRACT

A ring oscillator includes a chain of logic components. A storage element is associated with each logic component and configured to store a state of an output of the logic component to which the storage element is associated. A first circuit counts state transitions of an output of a given logic component of the chain. A second circuit synchronizes each storage with a clock signal. A third circuit determines a number of logic components crossed by a state transition between two edges of the clock signal. This determination is made based on the counted number of state transitions and on the stored states of the outputs.

### PRIORITY CLAIM

This application claims the priority benefit of French Application for Patent No. 2002212, filed on Mar. 5, 2020, the content of which is hereby incorporated by reference in its entirety to the maximum extent allowable by law.

### TECHNICAL FIELD

The present disclosure generally relates to electronic circuits and, more specifically, to integrated electronic circuits. The present disclosure more particularly relates to a digital circuit monitoring device.

### BACKGROUND

Known digital or sequential circuits comprise storage or sequencing elements, generally synchronous flip-flops, synchronized with a clock signal. Such digital circuits also comprise combinational paths formed of a plurality of logic or combinational components, that is, components having no storage function. Each combinational path couples the output of one flip-flop to the input of another flip-flop. A clock signal controls the timing, or sequencing, of the storages by the flip-flops.

For such a digital circuit to operate as expected, a time of propagation or of transmission of a signal in each combinational path of the circuit should be shorter than a predetermined duration minus a time margin. The predetermined duration corresponds, according to the considered combinational path, to the duration of a period, or cycle, of the clock signal or to the duration of a plurality of periods of the clock signal. The time margin is typically equal to the sum of a signal settling duration t_{hd} and of a signal hold duration tₛᵤ. The durations t_{hd} and tₛᵤ are determined so that a storage by a flip-flop is performed as expected if a signal delivered to a flip-flop data input is in a stable state for the entire duration tₛᵤ before an edge of the clock signal causing the storage, and the entire duration t_{hd} following this edge.

The combinational paths of a digital circuit having the longest propagation times are generally called critical paths.

Due to the manufacturing dispersions of a digital circuit, to the aging of the digital circuit, and/or to the operating conditions of the digital circuits, such as for example a temperature of the circuit and/or variations of the circuit power supply voltage, the propagation times in the combinational paths of the circuit may vary. In particular, when the propagation time of a signal in one of the combinational paths of the circuit, generally a critical path, increases, the propagation time may exceed the predetermined duration minus the time margin, which results in a malfunction of the circuit. A malfunction of the circuit may also result from a decrease in the propagation time of a signal in one of the combinational paths of the circuit.

To prevent such a malfunction, one or a plurality of monitoring devices of the digital circuit may be provided, the digital circuit and the monitoring devices being preferably implemented in a same integrated circuit. Such time drift monitoring devices enable to obtain information relative to the variation of the delays of propagation of a transition, or signal, through logic components. The information is then used to determine or estimate whether the propagation times in the combinational paths of the monitored circuit, in particular in the critical paths, vary, for example, whether the propagation time in one of the combinational paths of the circuit is capable of being longer than the predetermined duration of the considered combinational path, minus the time margin. When this is true, compensations may be implemented to avoid a malfunction of the circuit, for example, by adjusting the frequency of the clock signal, the power supply voltage of the integrated circuit, and/or the bias voltages of transistors of the integrated circuit.

There is a need to overcome all or part of the disadvantages of the above-described known monitoring devices.

### SUMMARY

An embodiment overcomes all or part of the disadvantages of the above-described known monitoring devices.

An embodiment provides a monitoring device sensitive to frequency variations of the clock signal of the digital circuit that it monitors.

An embodiment provides a monitoring device capable of providing information relative to the variation of the propagation delays of logic components within one clock cycle.

An embodiment provides a monitoring device capable of providing information relative to the variation of the propagation delays of logic components during any number of cycles of the clock signal.

An embodiment provides a monitoring device capable of providing information relative to the variation of the propagation delays of logic components which is more accurate than that provided by known monitoring devices such as described hereabove.

Thus, an embodiment provides a device comprising: a ring oscillator comprising a chain of logic components; an assembly of storage elements, each associated with a different logic component of said chain and configured to store a state of an output of said logic component to which said storage element is associated; a first circuit configured to count state transitions of an output of a given logic component of said chain; a second circuit configured to synchronize each storage with a clock signal; and a third circuit configured to determine a number of logic components of said chain crossed by a state transition between two edges of the clock signal, based on the counted number of state transitions and on the stored states of said outputs.

According to an embodiment, the third circuit is configured to determine a number of times when said state transition entirely runs through said chain between said two edges, based on the counted number of state transitions.

According to an embodiment, the third circuit is configured to determine a position of said state transition in said chain during an edge of the clock signal, based on the states of said outputs stored during said edge.

According to an embodiment, the third circuit is configured to determine the number of logic components crossed by said state transition between said two edges of the clock signal based on the number of times when said transition runs through the entire oscillator between said two edges, based on the position of the transition in said chain during a last one of said two edges and, possibly, based on the position of the transition in said chain during a first one of said two edges.

According to an embodiment, each logic component of said chain is associated with a storage element of said assembly.

According to an embodiment, the storage elements are latches.

According to an embodiment, each of the latches has an input coupled, preferably connected, to the output of the logic component having said latch associated therewith.

According to an embodiment, the first circuit comprises an input connected to an output of the latch having its input coupled, preferably connected, to the output of said given logic component.

According to an embodiment, the device comprises another assembly of storage elements, each associated with a different logic component of said chain and configured to store a state of the output of said logic component, said assembly and said other assembly being preferably configured so that each logic component associated with a storage element of said assembly is associated with a storage element of said other assembly.

According to an embodiment, the second circuit is configured so that the latches of said assembly are in the transparent state when the latches of said other assembly are in the latched state, and so that the latches of said assembly are in the latched state when the latches of said other assembly are in the transparent state, the second circuit being preferably configured so that the latches switch between the latched and transparent states at each changing of cycle of a succession of cycles of the clock signal.

According to an embodiment, the first circuit is configured to count the transitions from a first state to a second state, and from the second state to the first state.

According to an embodiment, the second circuit is configured to synchronize each storage with an active edge, preferably rising, of the clock signal.

According to an embodiment, one of the logic components of said chain, preferably said given logic component, is configured to prevent a propagation of an oscillation in the oscillator when a control signal is in a first state, and to allow the propagation of the oscillation when the control signal is in a second state, the second circuit being preferably configured to deliver the control signal in the second state between said two edges.

An embodiment provides an integrated circuit comprising a device such as described and a first digital circuit configured to be sequenced by said clock signal.

An embodiment provides a method comprising the steps of: counting by a first circuit state transitions of an output of a given logic component of a ring oscillator comprising a chain of logic components; storing states of the outputs of logic components of said chain in an assembly of storage elements, each associated with a different logic component; synchronizing using a second circuit said storages with a clock signal; and determining by a third circuit a number of logic components crossed by a state transition between two edges of the clock signal, based on the counted number of state transitions and on the stored states of said outputs.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 very schematically shows an embodiment of a monitoring device;

FIG. 2 shows timing diagrams illustrating the variation of signals of the device of FIG. 1 according to an implementation mode;

FIG. 3 very schematically shows another embodiment of a monitoring device;

FIG. 4 shows timing diagrams illustrating the variation of signals of the device of FIG. 3 according to an implementation mode;

FIG. 5 very schematically shows still another embodiment of a monitoring device; and

FIG. 6 shows timing diagrams illustrating the variation of signals of the device of FIG. 5 according to an implementation mode.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail. In particular, the known uses of the information relative to the propagation times of logic components, delivered by a monitoring device, have not been detailed, the described devices delivering information compatible with such known uses, and in particular with known compensations capable of being implemented based on the information to avoid a malfunction of a monitored digital device. Further, the known digital circuits which may be monitored by a monitoring device have not been described, the described monitoring devices being compatible with such known digital circuits.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order” of signify within 10%, and preferably within 5%.

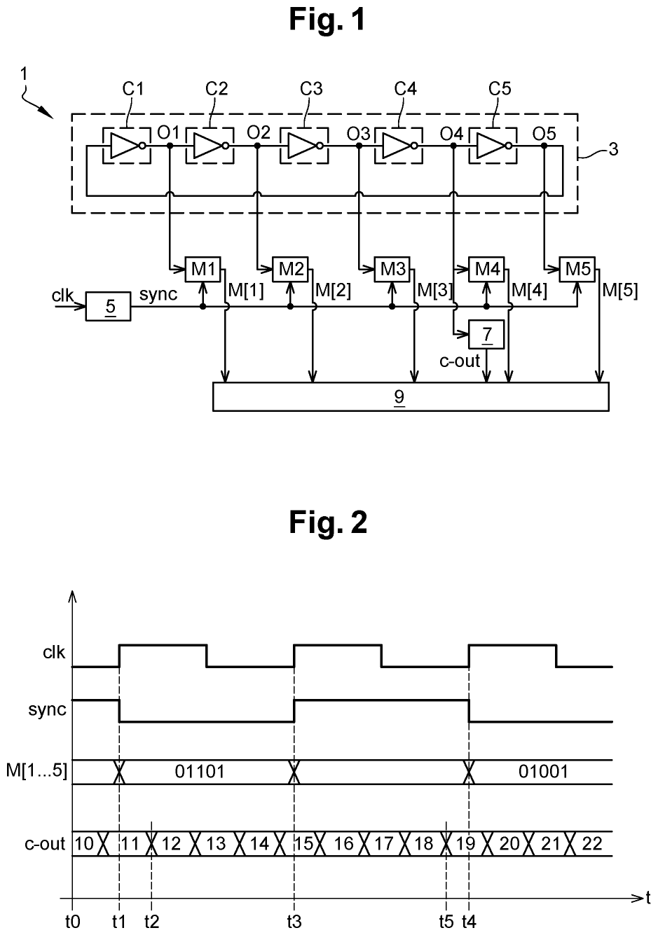

FIG. 1 very schematically shows an embodiment of a monitoring device 1.

Device 1 comprises a ring oscillator 3. Oscillator 3 comprises a chain of N logic components Ci (C1, C2, C3, C4, C5), i being an integer in the range from 1 to N. The components Ci of the chain are series-connected one after the others, the last component in the chain, that is, component C5 in the example of FIG. 1, having an output, O5 in the example of FIG. 1, connected to an input of the first component C1 of the chain. In other words, the chain is looped back, or closed, on itself. The number N of components Ci and the type of each component Ci are determined so that, when oscillator 3 is operating, or active, an output Oi of each component Ci oscillates between two (high and low) states, at a frequency determined by the time of propagation or of transmission of a signal through components Ci.

As an example, all the components Ci of the chain are identical, as in FIG. 1. In other examples, the chain comprises at least two different components Ci, for example, inverters, AND gates, OR gates, NOR gates, etc. The provision of a plurality of different components may enable to obtain information relative to the variation of the transmission times of different components having their propagation times varying differently due to manufacturing dispersions, to aging, and/or to modifications of operating conditions.

In the example of FIG. 1, components Ci all are inverters. In this case, the chain comprises an odd number N of inverters. In the example of FIG. 1, N is equal to 5.

Although, in the example of FIG. 1, number N of components Ci is equal to 5, in practice, oscillator 3 may comprise any number N greater than two of components Ci, N for example being greater than 10, preferably greater than 50, or even greater than 100.

Device 1 further comprises a set of storage elements Mj, j being an integer in the range from 1 to K, K being smaller than or equal to N. The term storage element Mj here designates a storage element Mj synchronous with a synchronization signal. Such a synchronous storage element Mj is configured to store the high or low state of its data input synchronously with an edge or a level of the synchronization signal, the stored state being available on the output M[j] of the storage element, and held at a stable value all along the storage. Flip-flops and latches are examples of synchronous storage elements.

Preferably, storage elements Mj are identical to one another. Further, the storages by elements Mj are performed simultaneously in all elements Mj, synchronously with a signal sync.

Each element Mj is associated with a different logic component Ci from oscillator 3. Each element Mj is configured to store the high or low state of the output Oi of the logic component Mi associated therewith, and to deliver the stored state on output M[j].

According to an embodiment, as shown in FIG. 1, the number K of elements Mj is equal to the number N of logic components Ci. In other words, each of components Ci is associated with a different element Mj. In the example of FIG. 1, components C1, C2, C3, C4, and C5 are associated with respective elements M1, M2, M3, M4, and M5.

Device 1 comprises a circuit 5 configured to deliver signal sync from a clock signal clk. More particularly, circuit 5 is configured to deliver a signal sync such that each storage in elements Mj is synchronous with an edge of signal clk, preferably an active edge of signal clk, for example, a rising edge of signal clk. In other words, circuit 5 is configured to synchronize each storage into elements Mj with signal clk.

Signal clk is preferably the clock signal which is delivered to a digital circuit (not shown) monitored by device 1, the storages in the flip-flops of the monitored digital circuit being implemented during active edges of the clock signal, for example, the rising edges of signal clk.

According to an embodiment, elements Mj are latches. When signal sync is in a first state, for example, the low state, each element Mj is said to be transparent and each state switching of its data input is copied on its output. When signal sync is in a second state, for example, the high state, each element Mj is said to be latched and the state of its output is held despite possible state switchings of its data input. The state of the data input of the latch is stored at the time when signal sync switches from the first state to the second state, the value of output M[j] of the latch being representative of the stored state and output value M[j] is held as long as signal sync is in the second state.

Device 1 comprises a circuit 7 configured to count state transitions of an output Oi of a given logic component Ci of oscillator 3. In other words, circuit 7 is configured to count transitions from the high state to the low state of output Oi and/or transitions from the low state to the high state of output Oi. Preferably, circuit 7 is configured to count transitions from the high state to the low state and transitions from the low state to the high state of output Oi. Circuit 7 comprises an input coupled or connected to output Oi. Circuit 7 delivers an output signal c-out representative of a number of counted transitions.

In this example, circuit 7 is configured to count the transitions of output O4 of component C4. Further, in this example, circuit 7 has an input connected to output O4 of logic component C4.

Device 1 comprises a circuit 9. Circuit 9 is configured to determine a number of logic components Ci of oscillator 3 crossed by a state transition between two edges of clock signal clk. For this purpose, circuit 9 receives signal c-out representative of the number of state transitions counted by circuit 7. Circuit 9 further receives the outputs M[j] of storage elements Mj, that is, the stored states of the outputs Oi of logic components Ci. In other words, circuit 9 receives a binary signal M[1, . . . , K] over K bits, corresponding to the concatenation of the K outputs M[j] of the storage elements Mj. As an example, in FIG. 1 where K is equal to 5, signal M[1, . . . , 5] comprises five bits respectively equal to M[1], M[2], M[3], M[4], and M[5].

Circuit 9 is configured to determine a number of times when a state transition has run all through the chain of components Ci of oscillator 3, based on signal c-out and on the number of state transitions that signal c-out represents. As an example, signal c-out is representative of a first number n1 during the first one of the two edges, and of a second number n2 during the last one of the two edges, indicating that there have been n1-n1-1 passages of the transition at the level of output O4 between the two edges. In other words, considering for example that components C5 and C4 are respectively the first and last components of the chain of components Ci, the transition has run n2-n1-1 times through the chain of components C5, C1, C2, C3, C4, taken in this order.

Further, circuit 9 is configured to determine a position of the state transition in the chain of oscillator 3 during an edge of the clock signal corresponding to a storage into elements Mj, based on the signal M[1, . . . , 5] representative of the states of the outputs Oi stored during this edge. As an example, in FIG. 1 where components Ci all are inverters, after an edge of signal clk causing a storage into elements Mj, if signal M[1, . . . , 5] is equal to “10010”, this means that at the time of this storage, component C3 had its input at the same state, for example, the low state, as its output O3, and thus that the transition, or oscillation, propagating through oscillator 3 was located at the level of the input of component C3 or, in other words, at the level of output O2 of component C2.

More particularly, based on signals c-out and M[1, . . . , 5], circuit 9 is capable of determining the position of a transition during a first one of two edges of signal clk, the number of full travels through oscillator 3 of the transition between the two edges of signal clk, and the position of the transition during the last one of the two edges of signal clk. Circuit 9 is further configured to determine, based on the above information, which of components Ci have been crossed by the transition between the two edges of signal clk, and how many times each of these components has been crossed by the transition between the two edges of signal clk. In other words, circuit 9 is capable of determining the number of components crossed by the transition between the two edges of signal clk.

According to an embodiment, the two edges of clock signal clk each correspond to a storage into elements Mj. In this embodiment, the position of the transition during the first one of the two edges is for example determined from signal M[1, . . . , K], and more particularly from the value of signal M[1, . . . , K] stored from this first edge. Such is, for example, the case in FIG. 1.

According to another embodiment, as will for example be described in further detail in FIG. 4, oscillator 3 is under control of a control signal, and is configured so that no oscillation propagates in oscillator 3 when the control signal is in a first state and so that an oscillation propagates in oscillator 3 when the control signal is in a second state. In such an embodiment, the switching of the control signal from its first state to its second state amounts to causing a state transition on an output Oi of a given component Ci, which then propagates in oscillator 3, causing the oscillation of outputs Oi. Thus, by providing for the control signal to switch from the first state to the second one during an edge of signal clk, the position of the transition during this first edge is known, even if this edge does not necessarily correspond to a storage by element Mj.

FIG. 2 shows timing diagrams illustrating the variation of signals of the device of FIG. 1 according to an implementation mode. More particularly, FIG. 2 illustrates the variation of signals clk, sync, M[1, . . . , K], and c-out. In FIG. 2, it is considered as an example that:

the number N of components Ci is equal to 5;

the number K of storage elements Mj is equal to 5;

components Ci all are inverters;

components Mj all are latches, configured to be transparent when signal sync is in the high state, and latched when signal sync is in the low state;

circuit 7 is configured to count all the state transitions on output O4 of component C4; and

circuit 5 is configured to switch the state of signal sync at each active edge, here, the rising edges, of signal clk.

At a time t0 at the beginning of the timing diagrams, signal clk is in the low state, signal sync is in the high state, signal M[1, . . . , 5] varies with the outputs Oi due to the fact that latches Mj are transparent, and signal c-out indicates that 10 transitions have been counted on output O4.

At a next time t1, corresponding to a rising edge of signal clk, signal sync is switched from its high state to its low state. Latches Mj then switch to the latched state and the state of outputs Oi at time t1 is stored, the value or the state of signal M[1, . . . , 5] from time t1 being representative of the stored state of outputs Oi at time t1. In this example, from time t1, signal M[1, . . . , 5] has value “01101”, which indicates that, at time t1, the transition propagating in oscillator 3 is located at the level of output O2 of component C2. From time t1 to the next increment of the value of signal c-out (time t2 subsequent to time t1—transition on output O4), the transition crosses components C3 and C4 in this order.

At time t1, signal c-out indicates that 11 transitions have been counted. As an example, the value of signal c-out at time t1 is stored by circuit 9.

At a time t3 subsequent to time t2 and corresponding to the next rising edge of signal clk, signal sync is switched to the high state and latches Mj then switch to the transparent state. The value of signal M[1, . . . , 5] from time t3 is then no longer representative of the state of outputs Oi at time t1.

At a next time t4, corresponding to the next rising edge of signal clk, the signal is switched to its low state. Latches Mj then switch to the latched state and the state of outputs Oi at time t4 is stored, the value or the state of signal M[1, . . . , 5] from time t4 being representative of the stored state of outputs Oi at time t4. In this example, from time t12, signal M[1, . . . , 5] has value “01001”, which indicates that, at time t4, the transition propagating in oscillator 3 is located at the level of output O3 of component C3. Thus, from the last increment of signal c-out (time t5 prior to time t4—transition on output O4), the transition has crossed components C5, C1, C2, and C3 in this order.

Further, at time t4, signal c-out indicates that 19 transitions have been counted. As an example, the value of signal c-out at time t4 is stored by circuit 9. From time t1, the transition propagating in oscillator 3 has thus crossed 19−11−1=7 times the chain of components C5, C1, C2, C3, and C4 in this order.

Circuit 9 deduces therefrom that, between times t1 and t4, the transition has crossed component C1 zero times between times t1 and t2, seven times between times t2 and t5, and one time between times t5 and t4, that is, a total of eight times between times t1 and t4. Similarly, circuit 9 determines that, between times t1 and t4, the transition has crossed eight times component C2, nine times component C3, eight times component C4, and eight times component C5.

In this example where components Ci are all identical, between times t1 and t4, the transition has crossed forty-one identical components Ci in series. It can, for example, be deduced from this information that the average propagation delay of a transition in a component Ci is equal to 2*T/41, T being the duration of a cycle, or period, of clock signal clk.

The calculations indicated hereabove are in practice implemented by circuit 9, only by means of the value of signal c-out and at times t1 and t4, and of the signal M[1, . . . , 5] representative of the state of the outputs Oi stored at times t1 and t4.

According to another example, circuit 7 has its input connected to the output M[j] of the element Mj having its input connected to the output Oi where circuit 7 counts the state transitions. For example, circuit 7 has its input connected to output M[4]. In this case, circuit 7 only counts the state transitions on output O4 when latch M4 is transparent, that is, for example, between times t3 and t4, referring to the timing diagrams of FIG. 2. Further, the position of the transition in oscillator 3 at times t3 and t4 is known due to the value taken by signal M[1, . . . , 5] from these respective times, which enables to determine the number of components Ci crossed by the transition between times t3 and t4. The connection of the input of circuit 7 to the output M[j] of a latch Mj enables the state of signals M[1, . . . , 5] and c-out to be stable between the same times or, in other words, the state of these signals to be stored at the same times. This enables to avoid, at a time when signal M[1, . . . , 5] is stored and indicates that the transition is located at the level of the output Oi where circuit 7 counts the transitions, for the transition not to have been counted yet by circuit 7. Indeed, this might lead to an error relative to the number of components Ci crossed by the transition which is determined from signals c-out and M[1, . . . , 5].

Examples where oscillator 3 comprises no means to enable, under control of a control signal, to block or to allow the propagation of a transition or oscillation in oscillator 3 have been described herein. In another example, oscillator 3 comprises such means configured to prevent the propagation of an oscillation through one of components Ci when the control signal is in a first state, and to allow the propagation of the oscillation through component Ci when the control signal is in a second state. When the propagation of the oscillation through a component Ci is blocked, this means that the state transition causing this oscillation is located at the input of component Ci, and its position is thus known.

Examples where elements Mj are latches have been described. Another example where elements Mj are D flip-flops, configured to copy the state of their data inputs on their respective outputs during an active edge, for example, rising, of the synchronization signal that they receive, and to hold the state of their respective outputs all the way to the next active edge of this signal, is considered. It is, for example, considered that signal clk is the synchronization signal of flip-flops Mj. Taking the example of the timing diagrams of FIG. 2, the value or state of signal M[1, . . . , 5] between times t1 and t3, between times t3 and t4, and between time t4 and a next active edge of signal clk, is representative of the state of outputs Oi at respective times t1, t3, and t4. Based on signal M[1, . . . , 5] and on the value of signal c-out at times t1, t3, and t4, circuit 9 can thus determine the number of components Ci crossed by a state transition between times t1 and t3, between times t3 and t4, and/or between times t1 and t4.

More generally, according to the type of storage elements Mj (flip-flop or latch), and to the synchronization signal delivered by circuit 5 to these elements, device 1, and more particularly its circuit 9, is configured to determine how many components Ci are crossed by a transition between two consecutive active edges of signal clk and/or between two non-consecutive active edges of signal clk, that is, two active edges separated from each other by at least another active edge.

Although this has not been illustrated in the Figures and has not been detailed in the examples described in relation with FIG. 2, circuit 9 may comprise storage circuits, for example, registers, sequenced by signal clk or signal sync, configured to store the state of signal M[1, . . . , 5] and the state of signal c-out. The provision of such storage means or circuits in circuit 9 and the implementation of circuit 9 are within the abilities of those skilled in the art based on the functional indications given hereabove.

Based on the number of elements Ci crossed by a transition between two edges of signal clk, that is, on the number of times when the transition has crossed each of elements Ci between the two edges of signal clk, information relative to the monitored digital circuit may be determined. As an example, when all components Ci are identical, the average time of propagation, between the two edges, of a transition through a component Ci may be determined. The average delay is then, for example, used to extrapolate the time of propagation of a signal in combinational paths of the monitored circuit, to verify whether the propagation times in each of the combinational paths is effectively shorter than or equal to the predetermined duration associated with this path, minus time margin t_{hd}+tₛᵤ, that is, to verify whether the monitored circuit operates as expected. If it does not, compensations may be implemented to prevent a malfunction of the monitored circuit.

Rather than using device 1, it could have been devised to use a device only comprising a ring oscillator, that is, a monitoring device which does not comprise storage elements Mj. The frequency of the oscillator would then have indicated the average propagation time in the components forming the oscillator chain.

However, such a device is insensitive to variations of signal clk. Thus, if the period T of signal clk decreases with respect to a nominal value for example defined on design of the circuit, this might not be detected by such a device, although such a decrease of the period T of signal clk may cause a malfunction of the monitored digital circuit.

Rather than using device 1, it could also have been devised to use a monitoring device currently called tunable replica circuit or TRC. Such a device comprises a replica, possibly programmable, of a combinational path of the monitored circuit. Such a device further comprises a time-to-digital converter or TDC synchronized with signal clk. In such a device, a state transition synchronized with an active edge of signal clk is delivered at the input of the combinational circuit replica, and the TDC converter delivers, at the next active edge of signal clk, a digital signal representative of the time of propagation of the transition in the combinational path replica.

However, a TRC-type monitoring device only operates when the time of propagation of a transition in the replicated combinational path is in the range from a minimum propagation time and a maximum propagation time determined by the TDC converter.

Further, a TRC-type monitoring device generally comprises a circuit introducing a propagation delay between the output of the replicated combinational path and the input of the TDC converter, so that, for nominal manufacturing and operating conditions, the time of propagation of a transition in the replicated combinational path is substantially in the middle of the range defined by the maximum and minimum propagation times that the TDC converter can measure. Due to the fact that the variations of propagation delays in the replicated combinational path and the variations of the propagation delays in the delay circuit are generally different, this may result in a measurement error.

The disadvantages mentioned in relation with the two above monitoring devices (ring oscillator and TRC-type device) are not present in device 1.

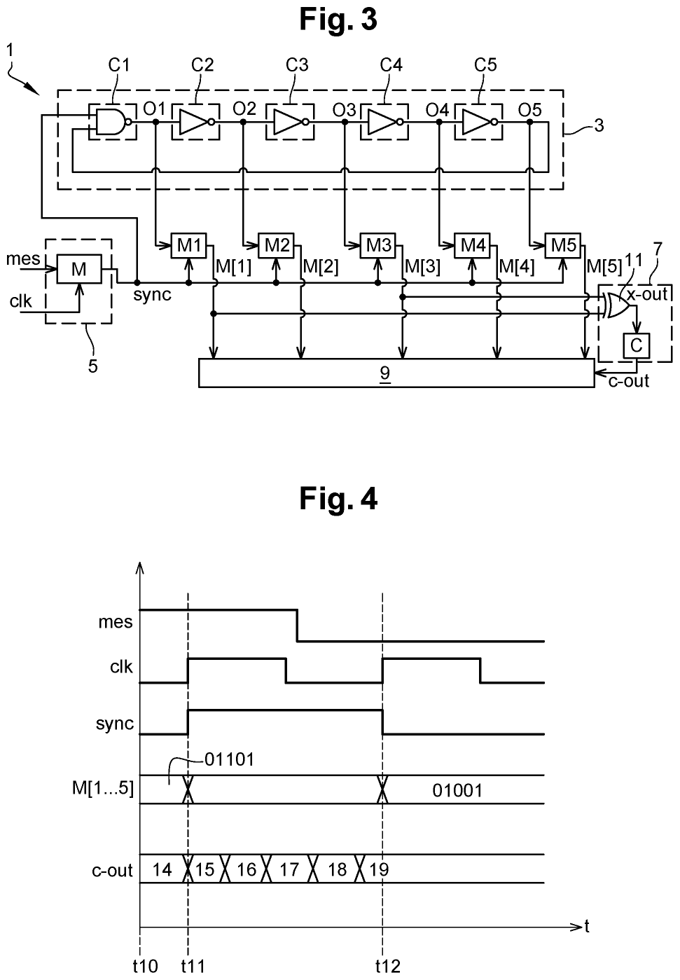

FIG. 3 very schematically shows another embodiment of a monitoring device 1. More particularly, FIG. 3 shows a specific embodiment of the general embodiment of device 1 described in relation with FIGS. 1 and 2. Only the differences between the device 1 of FIG. 1 and that of FIG. 3 are here detailed.

In the embodiment of FIG. 3, oscillator 3 comprises means, in the present example, component C1, configured to prevent oscillations in oscillator 3 when a control signal is in a first state, and to allow said oscillations when the control signal is in a second state. The control signal is obtained from signal clk, so that the control signal is in the second state between the two edges of signal clk between which device 1 determines how many elements Ci have been crossed by a transition. Preferably, the control signal is delivered by circuit 5.

In this example, the control signal is signal sync, component C1 is a NOR gate, and the other components Ci are inverters. Thus, the low state of signal sync blocks the transmission of a transition between the input and the output of component C1, and the high state of signal sync allows such a transmission.

Preferably, as in FIG. 3, when oscillator 3 comprises such a component C1 enabling to interrupt or to allow the propagation of a transition in oscillator 3, circuit 7 is configured to count the transitions on the output O1 of this component C1. In the example of FIG. 3, circuit 7 has an input connected to the output M[1] of element M1.

In the example of FIG. 3, elements Mj are latches, and an embodiment of circuit 7 is shown. In this embodiment, circuit 7 comprises a counter C delivering signal c-out, the number of transitions counted by counter C being incremented by one unit each time an input of counter C receives a rising edge of a signal x-out. Circuit 7 further comprises a component or logic gate 11 configured to deliver signal x-out. Signal x-out has a rising edge each time output O1 switches from the low state to the high state and each time this output switches from the high state to the low state, in the present example, if latches Mj are transparent. In this example, component 11 is an XOR gate having one input connected to output M[1] and another input connected to an output M[j] of another element Mj, in the present example the output M[3] of element M3.

It will be within the abilities of those skilled in the art to provide a connection of component 11 different from that described herein as an example and/or a component 11 other than an XOR gate, for example, in the case where components C2, C3, C4, and C5 would not all be inverters.

FIG. 3 shows an embodiment of circuit 5. Circuit 5 comprises a flip-flop M synchronized with the rising edges of signal clk, having its data input receiving a signal mes and its output delivering signal sync. Signal mes enables to select or to determine the number of cycles of signal clk when signal sync is in the high, respectively low, state. This enables to select the two active edges of signal clk between which device 1 determines the number of components Ci crossed by a transition.

It will be within the abilities of those skilled in the art to provide other ways of implementing circuit 5. For example, in the case where the state of signal sync is switched at each rising edge of signal clk, circuit 5 may be implemented with a frequency divider configured to deliver signal sync at a frequency twice lower than that of signal clk.

FIG. 4 shows timing diagrams illustrating the variation of signals of the device of FIG. 3 according to an implementation mode. More particularly, FIG. 4 illustrates the variation of signals mes, clk, sync, M[1, . . . , 5], and c-out. In FIG. 4, it is considered as an example that:

the number N of components Ci is equal to 5;

the number K of storage elements Mj is equal to 5;

component C1 is a NOR gate such as previously described, the other components Ci all being inverters;

components Mj all are latches, configured to be transparent when signal sync is in the high state, and latched when signal sync is in the low state;

circuit 7 is implemented and connected as illustrated in FIG. 3; and

circuit 5 is configured to switch the state of signal sync at each rising edge of signal clk.

At a time t10 at the beginning of the timing diagram, signal mes is in the high state, signal clk is in the low state, signal sync is in the low state, latches Mj are in the locked state, and signal c-out is in a stored state, signal c-out indicating in the present example that 14 transitions have been counted. Further, due to the fact that signal sync in the low state, output O1 is necessarily in the high state. As a result, outputs O2, O3, O4, and O5 respectively are in the low, high, low, and high state, signal x-out is in the low state, and the propagation of an oscillation through oscillator 3 is blocked at the level of the input of component C1.

At a next time t11, corresponding to a next rising edge of signal clk, due to the fact that signal mes is in the high state, signal sync switches to the high state and the latches switch to the transparent state. The switching of signal sync to the high state further causes the switching of output O1 to the low state, and oscillator 3 starts oscillating. Such a switching of output O1 to the low state is transmitted to output M[1] of latch M1, while the high state of output O3 is transmitted to output M[3] of latch M3. As a result, signal x-out switches to the high state. Signal c-out, which has value 14 at time t11, is then incremented by one unit, little after time t11, as a result of the rising edge of signal x-out.

At a next time t13, corresponding to the next rising edge of signal clk, due to the fact that signal mes has been switched to the low state between times t11 and t12 and has then been held in the low state until time t12, signal sync is switched to the low state and latches Mj switch to the latched state. The state of outputs Oi at time t12 is then stored, the value of signal M[1, . . . , 5] from time t12 being representative of the stored state of outputs Oi at time t12. In this example, from time t12, signal M[1, . . . , 5] has value “01001”, which indicates that, at time t12, the transition propagating in oscillator 3 is located at the level of output O3 of component C3. Further, the switching of latches Mj to the latched state results in that the value of signal c-out at time t12 is also stored, here, at value 19, which indicates that, between times t11 and t12, circuit 7 has counted 19−14=5 state transitions on output O1. Further, the switching of signal sync to the low state at time t1 causes the stopping of the oscillations in oscillator 3.

Thus, the value of signal c-out at times t11 and t12 is known, the state of outputs Oi at time t11 is known due to the low state of signal sync at time t11, which indicates that the state transition propagating in oscillator 3 is blocked on output O5 of component C5, and that the state of outputs Oi at time t12 is known via the stored value of signal M[1, . . . , 5] from time t12, which indicates that the state transition propagating in oscillator 3 is located on output O3 of component C3 at time t12. Circuit 9 then is capable of determining that, between times t11 and t12, the state transition has first crossed component C1, and then has crossed 19−14−1=4 times the chain of components C2, C3, C4, C5, and C1, taken in this order, and has finally crossed components C2 and C3. In other words, between times til and t12, the state transition propagating through oscillator 3 has crossed 1+4*5+2=23 components Ci. More particularly, the transition has crossed 5 times component C1, 5 times component C2, 5 times component C3, 4 times component C4, and 4 times component C5.

In this embodiment where oscillator 3 comprises logic component C1 enabling to interrupt or to allow the propagation of a transition in oscillator 3, the storage of the state of outputs Oi at times t11, via signal M[1, . . . , 5], is not useful. Indeed, the position of the transition at time t11 is imposed by component C1 and signal sync.

According to an embodiment, before each switching of signal sync to the state where latches Mj are transparent, the counter C of circuit 7 is reset. As an example, such a resetting of counter C is controlled by a switching of signal mes from the low state to the high state which has occurred during the cycle of signal clk preceding time t11. In this case, the storage of signal c-out at time t11 by circuit 9 is not useful.

Still according to this embodiment, advantageously, circuit 9 may be implemented by a simple logic and arithmetic unit, comprising no storage function, and by a combinational circuit configured to convert signal M[1, . . . , 5] into a value n3 corresponding to the number of components Ci crossed by a transition from the last increment of signal c-out and time t12 when signal M[1, . . . , 5] is stored. Taking the example of FIG. 4, and considering as an example the case where counter C is initialized at value n1=0 before time t11, signal c-out would have been at value n2=5 at time t12, and value n3 would have been equal to 2. Circuit 9 would then have determined that the number of components Ci crossed between times t11 and t12 is equal to N*(n2−1)+n3+1=23, the increment by 1 corresponding to the passing of the transition in component Cl just after time t11.

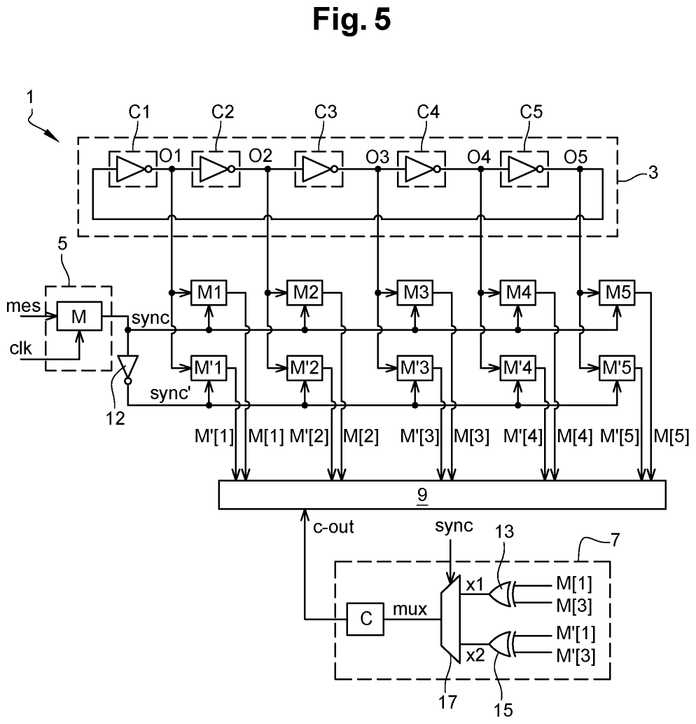

FIG. 5 very schematically shows still another embodiment of a monitoring device 1. More particularly, FIG. 5 shows a specific embodiment of the general embodiment of device 1 described in relation with FIGS. 1 and 2. Only the differences between the device 1 of FIG. 1 and that of FIG. 5 are here detailed.

In the embodiment of FIG. 5, in addition to the assembly of storage elements Mj, device 1 comprises another assembly of storage elements M′q, q being an integer in the range from 1 to K′, K′ being smaller than or equal to N, preferably equal to K. Each storage element M′q is configured to synchronously store the high or low state of its data input with an edge or a level of the synchronization signal sync' obtained from signal clk, the stored state being available on output M′[q] of the storage element, and held at a stable value all along the storage. Preferably, storage elements M′q are identical to one another and to elements Mj.

Storage elements Mj and M′q here are latches. Further, circuit 5 delivers synchronization signal sync to elements Mj and synchronization signal sync' to elements M′q. Signals sync and sync' are such that, when latches Mj are transparent, latches M′q are latched and, conversely, when latches Mj are latched, latches M′q are transparent.

Preferably, there are as many elements Mj as elements M′q, and for each element Mj associated with a component Ci, a corresponding element M′q is associated with component Ci. In other words, two elements Mj and M′q associated with a same component Ci are configured to store the output state Oi of this component Ci, synchronously with respective signals sync and sync'.

Circuit 9 receives the output signals M[j] of latches Mj and the output signals M′[q] of latches Mq. Signals M′[q], M[j], and c-out, for example, enable circuit 9 to determine at each cycle of signal clk how many components Ci have been crossed by a transition during this cycle. In other words, this enables to avoid for there to be periods between two active edges of signal clk where the device does not determine the number of components Ci crossed by a transition between the two active edges.

FIG. 5 shows an embodiment of circuit 5. In this embodiment, circuit 5 comprises a flip-flop M synchronized with the rising edges of signal clk. The data input of flip-flop M receives signal mes, and the output of flip-flop M delivers signal sync. Further, signal sync' here corresponds to the logic complement of signal sync, that is, signal sync' is in the low state when signal sync is in the high state, and conversely. In this example, signal sync' is obtained at the output of an inverter 12 having its input receiving signal sync. In another example, flip-flop M comprises two outputs respectively delivering signals sync and sync'.

It will be within the abilities of those skilled in the art to provide other ways of implementing circuit 5.

In this embodiment, circuit 7 is configured to count the transitions on output O1 of component C1. More particularly, in this example, circuit 7 has an input connected to the output of latch M1 to be able to count the state transitions on output O1 when latch M1 is in the transparent state, and another input connected to the output of latch M′1 to be able to count the state transitions on output O1 when latch M′1 is in the transparent state. In another example, not illustrated, circuit 7 is directly connected to output O1.

FIG. 5 shows an embodiment of circuit 7. Circuit 7 comprises a counter C delivering signal c-out, the number of transitions counted by counter C being incremented by one unit each time an input of counter C receives a rising edge of a signal mux. Circuit 7 further comprises a component or logic gate 13 configured to deliver a signal x1 having a rising edge each time output O1 switches from the low state to the high state and each time this output switches from the high state to the low state, if latches Mj are transparent. In this example, component 13 is an XOR gate having an input connected to output M[1] and another input connected to an output M[j] of another element Mj, in the present example the output M[3] of element M3. Similarly, circuit 7 further comprises a component or logic gate 15 configured to deliver a signal x2 having a rising edge each time output O1 switches from the low state to the high state and each time this output switches from the high state to the low state, if latches M′q are transparent. In this example, component 15 is an XOR gate, having an input connected to output M′[1] and having another input connected to an output M′[q] of another element M′q, in this example, the output M′[q] of element M′3. Circuit 7 comprises a component 17 configured so that signal mux is signal x1 when latches Mj are transparent, and so that signal mux is signal x2 when latches M′q are transparent. Component 17 is for example a multiplexer comprising two inputs receiving respective signals x1 and x2, a control input receiving signal sync or sync', and an output delivering signal mux.

It will be within the abilities of those skilled in the art to provide other ways of implementing component 7 and/or other ways of coupling component 7 to one or a plurality of outputs Oi.

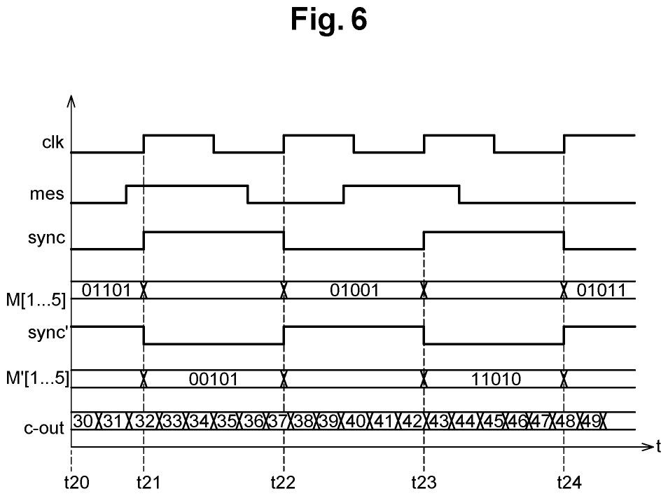

FIG. 6 shows timing diagrams illustrating the variation of signals of the device of FIG. 5 according to an implementation mode. More particularly, FIG. 6 illustrates the variation of signals clk, mes, sync, M[1, . . . , 5], sync', M′[1, . . . , 5], and c-out, signal M′[1, . . . , 5] corresponding to the concatenation of outputs M′[1], M′[2], M′[3], M′[4], and M′[5], taken in this order. In FIG. 6, it is considered as an example that circuits 5 and 7 are such as shown and connected in FIG. 5, and that circuit 5 delivers a signal sync switching at each active edge, in the present example at each rising edge, of signal clk.

At a time t20 of beginning of the timing diagrams, signals clk, mes, and sync are in the low state and signal sync' is in the high state. Latches Mj and M′q are thus respectively latched and transparent. Although this is not shown in FIG. 6, counter C then receives signal x2.

Before a next time t21 corresponding to the next rising edge of signal clk, signal mes is switched to the high state. Thus, at time t21, signals sync and sync' respectively switch to the high state and to the low state, latches Mj and M′q respectively switching to the transparent state and to the latched state. The states of outputs Oi at time t21 is stored, the value or the state of signal M′[1, . . . , 5] from time t21 being representative of the stored state of outputs Oi at time t21. In this example, from time t21, signal M′[1, . . . , 5] has value “00101”, which indicates that, at time t21, the transition propagating in oscillator 3 is located at the level of output O5 of component C5.

Further, at time t21, signal c-out is at value 32, and, although this is not shown in FIG. 6, counter C receives signal x1 from time t21.

Before a next time t22 corresponding to the next rising edge of signal clk, signal mes is switched to the low state. Thus, at time t22, signals sync and sync' respectively switch to the low state and to the high state, latches Mj and M′q respectively switching to the latched state and to the transparent state. The state of outputs Oi at time t22 is stored, the value or the state of signal M[1, . . . , 5] from time t22 being representative of the stored state of outputs Oi at time t22. In this example, from time t22, signal M[1, . . . , 5] has value “01001”, which indicates that, at time t22, the transition propagating in oscillator 3 is located at the level of output O3 of component C3.

Further, at time t22, signal c-out is at value 37 and, although this is not shown in FIG. 6, counter C receives signal x2 from time t22.

Before at next time t23 corresponding to the next rising edge of signal clk, signal mes is switched to the high state. Thus, at time t23, signals sync and sync' respectively switch to the high state and to the low state, latches Mj and M′q respectively switching to the transparent state and to the latched state. The state of outputs Oi at time t23 is stored, the value or the state of signal M′[1, . . . , 5] from time t23 being representative of the stored state of outputs Oi at time t23. In this example, from time t23, signal M′[1, . . . , 5] has value “11010”, which indicates that, at time t23, the transition propagating in oscillator 3 is located at the level of output O5 of component C5.

Further, at time t23, signal c-out is at value 42 and, although this is not shown in FIG. 6, counter C receives signal x1 from time t23.

Before a next time t24 corresponding to the next rising edge of signal clk, signal mes is switched to the low state. Thus, at time t24, signals sync and sync' respectively switch to the low state and to the high state, latches Mj and M′q respectively switching to the latched state and to the transparent state. The state of outputs Oi at time t24 is stored, the value or the state of signal M[1, . . . , 5] from time t24 being representative of the stored state of outputs Oi at time t24. In this example, from time t24, signal M[1, . . . , 5] has value “01011”, which indicates that, at time t23, the transition propagating in oscillator 3 is located at the level of output O4 of component C4.

Further, at time t24, signal c-out is at value 48 and, although this is not shown in FIG. 6, counter C receives signal x2 from time t24.

Based on the values of signal c-out and on the position of the transition in oscillator 3 at each of times t21, t22, t23, and t24, according to an embodiment, circuit 9 is capable of determining, similarly to what has been previously described in relation with FIGS. 2 and 4, the number of components Ci crossed by the transition between times t21 and t22, between times t22 and t23, and between times t23 and t24, that is, the number of components Ci crossed at each cycle of signal clk.

This, for example, enables to obtain, for each cycle of signal clk, an average value of the transmission delay in a component Ci, this average value then being sensitive to fast variations of operating conditions, that is, variations, for example, of the power supply voltage, having a duration shorter than that of a cycle of signal clk.

Based on the same values of signal c-out and on the position of the transition in oscillator 3 at each of times t21, t22, t23, and t24, according to another embodiment, circuit 9 is capable of determining the number of components Ci crossed by the transition between two edges of signal clk selected among the edges occurring at times t21, t22, t23, and t24.

This, for example, enables to obtain an average value of the transmission delay in a component Ci during a plurality of cycles of signal clk, the average value being less sensitive to fast variations of operating conditions, and thus more sensitive to slow variations of operating conditions, for example, variations due to aging.

The two above embodiments may be combined.

Embodiments where each component Ci is associated with at least one storage element configured to store the state of the output Oi of this component Ci during active edges of signal clk have been described hereabove in relation with FIGS. 1 to 6. In alternative embodiments, only certain components Ci are associated with such a storage element. In such variants, the position of the transition in oscillator 3 is then less accurately determined, whereby the determination of the number of components Ci crossed by the transition between two edges of signal clk is less accurate.

Various embodiments and variants have been described. Those skilled in the art will understand that certain features of these embodiments can be combined and other variants will readily occur to those skilled in the art. In particular, it will be within the abilities of those skilled in the art to provide other implementations of ring oscillator 3, of circuit 5, of circuit 7, and/or of circuit 9, provided that:

device 1 comprises an assembly of synchronous storage elements configured to store the state of at least certain outputs of the components Ci forming oscillator 3;

circuit 5 is configured to synchronize the storages in such storage elements with edges of clock signal clk;

circuit 7 is configured to count state transitions occurring on the output Oi of one of components Ci; and

circuit 9 is configured to determine a number of components Ci crossed by a state transition propagating in oscillator 3 between two edges of the clock signal, based on a counted number of state transitions delivered by circuit 7 and on the stored states of the outputs delivered by the storage elements. For example, it will be within the abilities of those skilled in the art to provide for the ring oscillator to comprise a replica, possibly programmable, of a combinational path of the monitored circuit, and/or one or a plurality of programmable logic components.

Finally, the practical implementation of the described embodiments and variations is within the abilities of those skilled in the art based on the functional indications given hereabove. In particular, it will be within the abilities of those skilled in the art to implement circuit 9, possibly by providing storage circuits such as registers, to store, synchronously with signal clk, signal sync, and/or signal sync', signals M[1, . . . , K], M[1, . . . , K′] and/or c-out. For example, referring to the example of FIG. 6, it will be within the abilities of those skilled in the art to provide storage means configured to store signal c-out at each rising edge of signal clk (times t21, t23, t24, etc.).

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

1. A device, comprising:
a ring oscillator comprising a chain of logic components;
a first assembly of storage elements, wherein each storage element is associated with a different logic component of said chain and is configured to store a state of an output of said logic component to which said storage element is associated;
a first circuit configured to count a number of state transitions of an output of a given logic component of said chain;
a second circuit configured to synchronize each storing of the state with a clock signal; and
a third circuit configured to determine a number of logic components of said chain crossed by a state transition between two edges of the clock signal, wherein said determined number of logic components is based on the counted number of state transitions and on the stored states of said outputs from said first assembly;
wherein one of the logic components of said chain is configured to prevent a propagation of an oscillation in the oscillator in response to a control signal in a first state, and to allow the propagation of the oscillation in response to the control signal in a second state; and
wherein the second circuit is configured to generate said control signal and deliver the control signal in the second state between said two edges of the clock signal.

2. The device according to claim 1, where said one of the logic components of said chain is said given logic component.

3. The device according to claim 1, wherein the third circuit is further configured to determine a number of times when said state transition entirely runs through said chain between said two edges, wherein determination of the number of times is based on the counted number of state transitions.

4. The device according to claim 1, wherein the third circuit is further configured to determine a position of said state transition in said chain during an edge of the clock signal, wherein determination of the position is based on states of said outputs stored during said edge.

5. The device according to claim 4, wherein the third circuit is further configured to determine a number of times when said state transition entirely runs through said chain between said two edges, wherein determination of the number of times is based on the counted number of state transitions.

6. The device according to claim 5, wherein the third circuit is further configured to determine the number of logic components crossed by said state transition between said two edges of the clock signal based on: the number of times when said transition runs through the entire oscillator between said two edges and the position of the transition in said chain during a last one of said two edges.

7. The device according to claim 6, wherein the third circuit is configured to determine the number of logic components crossed by said state transition between said two edges of the clock signal further based on the position of the transition in said chain during a first one of said two edges.

8. The device according to claim 1, wherein each logic component of said chain is associated with a storage element of said first assembly.

9. The device according to claim 1, wherein the storage elements are latches.

10. The device according to claim 9, wherein each of the latches has an input coupled to receive the output of the logic component to which said latch is associated.

11. The device according to claim 10, wherein the first circuit comprises an input connected to an output of the latch having its input coupled to the output of said given logic component.

12. The device according to claim 1, further comprising a second assembly of storage elements, wherein each storage element of the second assembly is associated with a different logic component of said chain and configured to store a state of the output of said logic component, said first assembly and said second assembly being configured so that each logic component associated with one storage element of said first assembly is further associated with one storage element of said second assembly.

13. The device according to claim 12, wherein the second circuit is configured so that storage elements of said first assembly are in a transparent state when storage elements of said second assembly are in a latched state, and so that storage elements of said first assembly are in the latched state when storage elements of said second assembly are in the transparent state, the second circuit being configured so that the storage elements switch between the latched and transparent states at each changing of cycle of a succession of cycles of the clock signal.

14. The device according to claim 1, wherein the first circuit is configured to count the transitions from a first state to a second state, and from the second state to the first state.

15. The device according to claim 1, wherein the second circuit is configured to synchronize each storage with an active edge of the clock signal.

16. A device, comprising:
a ring oscillator comprising a chain of logic components;
a first assembly of first storage elements, wherein each first storage element is associated with a different logic component of said chain and is configured to store a state of an output of said logic component to which said storage element is associated;
a second assembly of second storage elements, wherein each second storage element is associated with a different logic component of said chain and configured to store a state of the output of said logic component, said first assembly and said second assembly being configured so that each logic component associated with one first storage element of said first assembly is further associated with one second storage element of said second assembly;
a first circuit configured to count a number of state transitions of a logical combination of outputs of at least two logic components of said chain;
a second circuit configured to synchronize each storing of the state with a clock signal; and
a third circuit configured to determine a number of logic components of said chain crossed by a state transition between two edges of the clock signal, wherein said determined number of logic components is based on the counted number of state transitions and on the stored states of said outputs in the first and second assemblies.

17. The device according to claim 16, wherein the third circuit is further configured to determine a number of times when said state transition entirely runs through said chain between said two edges, wherein determination of the number of times is based on the counted number of state transitions.

18. The device according to claim 16, wherein the third circuit is further configured to determine a position of said state transition in said chain during an edge of the clock signal, wherein determination of the position is based on states of said outputs stored during said edge.

19. The device according to claim 18, wherein the third circuit is further configured to determine a number of times when said state transition entirely runs through said chain between said two edges, wherein determination of the number of times is based on the counted number of state transitions.

20. The device according to claim 19, wherein the third circuit is further configured to determine the number of logic components crossed by said state transition between said two edges of the clock signal based on: the number of times when said transition runs through the entire oscillator between said two edges and the position of the transition in said chain during a last one of said two edges.

21. The device according to claim 20, wherein the third circuit is configured to determine the number of logic components crossed by said state transition between said two edges of the clock signal further based on the position of the transition in said chain during a first one of said two edges.

22. The device according to claim 16, wherein each logic component of said chain is associated with a storage element of said first assembly.

23. The device according to claim 16, wherein the storage elements are latches.

24. The device according to claim 23, wherein each of the latches has an input coupled to receive the output of the logic component to which said latch is associated.

25. The device according to claim 24, wherein the first circuit comprises an input connected to an output of the latch having its input coupled to the output of said given logic component.

26. The device according to claim 16, wherein the second circuit is configured so that storage elements of said first assembly are in a transparent state when storage elements of said second assembly are in a latched state, and so that storage elements of said first assembly are in the latched state when storage elements of said second assembly are in the transparent state, the second circuit being configured so that the storage elements switch between the latched and transparent states at each changing of cycle of a succession of cycles of the clock signal.

27. The device according to claim 16, wherein the first circuit is configured to count the transitions from a first state to a second state, and from the second state to the first state.

28. The device according to claim 16, wherein the second circuit is configured to synchronize each storage with an active edge of the clock signal.

29. The device according to claim 16, wherein one of the logic components of said chain is configured to prevent a propagation of an oscillation in the oscillator in response to a control signal in a first state, and to allow the propagation of the oscillation in response to the control signal in a second state, and wherein the second circuit is configured to generate said control signal and deliver the control signal in the second state between said two edges.

30. The device according to claim 30, where said one of the logic components of said chain is said given logic component.
